(19) United States
(12) Patent Application Publication
(10) Pub. No.: US 2018/0149609 A1
(43) Pub. Date: May 31, 2018

(54) ELECTRODE AND METHOD FOR MAKING AN ELECTRODE

(71) Applicant: SAINT-GOBAIN PERFORMANCE PLASTICS CORPORATION, Solon, OH (US)

(72) Inventors: Antoine DIGUET, Paris (FR); Anne Lelarge, Paris (FR)

(21) Appl. No.: 15/817,558

(22) Filed: Nov. 20, 2017

Related U.S. Application Data
(60) Provisional application No. 62/428,054, filed on Nov. 30, 2016.

(51) Int. Cl. G01N 27/327; H01B 1/02; H01B 5/14; C23C 14/34

(52) U.S. Cl. CPC G01N 27/327; H01B 1/02; C22C 19/05; C23C 14/34; H01B 5/14

(57) ABSTRACT

An electrode may include a substrate, an adhesive layer, a first layer and a second layer. The first layer may include Ag, Cu, Ru or a combination thereof. The second layer may include Au. The second layer may have a thickness of not grater than about 25 nm. The adhesive layer may be disposed between the substrate and the first layer. The first layer may be disposed between the adhesive layer and the second layer.

### CROSS-REFERENCE TO RELATED APPLICATION

This application claims priority under 35 U.S.C. § 119(e) to U.S. Provisional Patent Application No. 62/428,054, entitled “ELECTRODE AND METHOD FOR MAKING AN ELECTRODE,” by Antoine DIGUET et al., filed Nov. 30, 2016, which is assigned to the current assignee hereof and is incorporated herein by reference in its entirety.

### FIELD OF THE DISCLOSURE

The present disclosure relates to an electrode, and more particularly to, a thin film electrode for biosensor applications.

### RELATED ART

Electrochemical glucose biosensors generally include two electrodes with at least one of the electrodes having a metallic layer. This metallic layer can be chosen for a variety of factors, including a combination of the metals resistivity and electrochemical inertness. However, metals that generally meet such requirements for use in electrochemical glucose biosensors can be expensive and any reduction in their quantity or quality can degrade the overall performance of the biosensors. So, there is a continuing need for an electrode design that can be manufactured in a cost effective manner while still maintaining or improving overall performance.

### SUMMARY

According to a first aspect, an electrode may include a substrate, an adhesive layer, a first layer and a second layer. The first layer may include Ag, Cu, Ru or a combination thereof. The second layer may include Au. The second layer may have a thickness of not greater than about 25 nm. The adhesive layer may be disposed between the substrate and the first layer. The first layer may be disposed between the adhesive layer and the second layer.

According to another aspect, an electrode may include a substrate, an adhesive layer, a first layer and a second layer. The first layer may include Ag, Cu, Ru or a combination thereof. The second layer may include Au. The first layer may have a thickness of at least about 5 nm. The adhesive layer may be disposed between the substrate and the first layer. The first layer may be disposed between the adhesive layer and the second layer.

According to yet another aspect, an electrode may include a substrate, an adhesive layer, a first layer and a second layer. The first layer may include Ag, Cu, Ru or a combination thereof. The second layer may include Au. The adhesive layer may be disposed between the substrate and the first layer. The first layer may be disposed between the adhesive layer and the second layer. The electrode may have a layer thickness ratio L1_{TH}/L2_{TH} of at least about 0.7, where L1_{TH} is the thickness of the first layer and L2_{TH} is the thickness of the second layer.

According to still another aspect, an electrode may include a substrate, an adhesive layer, a first layer and a second layer. The first layer may include Ag, Cu, Ru or a combination thereof. The second layer may include Au. The first layer may have a thickness of at least about 5 nm and not greater than about 30 nm. The second layer may have a thickness of at least about 5 nm and not greater than about 25 nm. The adhesive layer may be disposed between the substrate and the first layer. The first layer may be disposed between the adhesive layer and the second layer.

According to another aspect, biosensor test strip may include an electrode system that may include an electrode. The electrode may include a substrate, an adhesive layer, a first layer and a second layer. The first layer may include Ag, Cu, Ru or a combination thereof. The second layer may include Au. The adhesive layer may be disposed between the substrate and the first layer. The first layer may be disposed between the adhesive layer and the second layer. The electrode may have a layer thickness ratio L1_{TH}/L2_{TH} of at least about 0.7, where L1_{TH} is the thickness of the first layer and L2_{TH} is the thickness of the second layer.

According to still another aspect, a method of forming an electrode may include providing a substrate, depositing an adhesive layer on the substrate, depositing a first layer over the adhesive layer and depositing a second layer of the first layer. The first layer may include Ag, Cu, Ru or a combination thereof. The second layer may include Au. The electrode may have a layer thickness ratio L1_{TH}/L2_{TH} of at least about 0.7, where L1_{TH} is the thickness of the first layer and L2_{TH} is the thickness of the second layer.

### BRIEF DESCRIPTION OF THE DRAWINGS

Embodiments are illustrated by way of example and are not limited by the accompanying figure.

FIG. 1 includes an illustration of an electrode according to embodiments described herein; and

FIG. 2 includes a plot of the cyclic voltammetry curves for sample electrode embodiments described herein and comparative sample embodiments described herein.

Skilled artisans appreciate that elements in the figures are illustrated for simplicity and clarity and have not necessarily been drawn to scale. For example, the dimensions of some of the elements in the figures can be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but can include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item can be used in place of a single item. Similarly, where more than one item is described herein, a single item can be substituted for that more than one item.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the electrode and biosensor arts.

Embodiments described herein are generally directed to an electrode or a method of forming an electrode where the electrode includes a substrate, an adhesive later, a first layer, and a second layer. The first layer may include Ag, Cu, Ru or a combination thereof. The second layer may include Au. The adhesive layer may be disposed between the substrate and the first layer. The first layer may be disposed between the adhesive layer and the second layer.

In certain embodiments, an electrode formed according to embodiments described herein can be a thin film electrode. According to still other embodiments, the thin film electrode can be for us in biosensors or biosensor test strips that measure the glucose level in a sample, such as, a blood sample.

According to still other embodiments described herein, a biosensor or biosensor test strip may include an electrode formed according to embodiments described herein. For example, a biosensor or biosensor test strip may include an electrode includes a substrate, an adhesive later, a first layer, and a second layer. The first layer may include Ag, Cu, Ru or a combination thereof. The second layer may include Au. The adhesive layer may be disposed between the substrate and the first layer. The first layer may be disposed between the adhesive layer and the second layer.

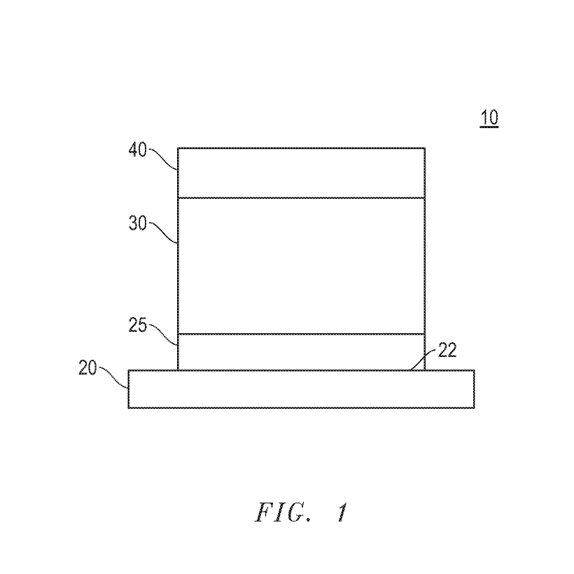

FIG. 1 includes an illustration showing the configuration of an electrode 10 formed according to embodiments described herein. As shown in FIG. 1, electrode 10 may include a substrate 20, an adhesive layer 25, a first layer 30 and a second layer 40. As illustrated, the adhesive layer 25 may be disposed between the substrate 20 and the first layer 30. The first layer 30 can be disposed adjacent to the adhesive layer 25 and the second layer 40 can be disposed adjacent to the first layer 30 such that the first layer 30 is located between the adhesive layer 25 and the second layer 40.

According to certain embodiments, the adhesive layer 25 can directly contact the substrate 20, the first layer 30, or both. For example, the adhesive layer 25 can be disposed directly adjacent the substrate 20 such that the adhesive layer 25 is directly contacting the substrate 20. According to certain other embodiments, the first layer 30 can directly contact the adhesive layer 25, the second layer 40, or both. For example, the first layer 30 can be disposed directly adjacent the adhesive layer 25 such that the first layer 30 is directly contacting the adhesive layer 25. Additionally, the second layer 40 can be disposed directly adjacent the first layer 30 such that the second layer 40 is directly contacting the first layer 30.

According to still other embodiments, the electrode 10 can include additional layers. For example, the electrode 10 can include an intermediate layer or intermediate layers (not show in FIG. 1) disposed between one or more of the substrate 20, the adhesive layer 25, the first layer 30, and the second layer 40.

According to yet other embodiments, the electrode 10 formed as described herein may be an inert electrode, such as, an inert thin film electrode.

In certain embodiments, the electrode 10 can be a biosensor electrode, such as, for example, a biosensor electrode that can measure the glucose level of a sample, such as, a blood sample. In particular embodiments, the electrode 10 can contain a layer comprising a chemical solution (not shown in FIG. 1), such as a solution containing an enzyme, a mediator, an indicator, or any combination thereof. In particular embodiments, the electrode 10 can be reactive to glucose. For example, glucose can be indirectly degraded by the electrode 10 by first reacting with an enzyme to form a subproduct and the electrode 10 is reactive with the subproduct.

According to still other embodiments, the electrode 10 can be part of a biosensor, such as, a biosensor test strip adapted to measure the level of glucose in a sample, such as, a blood sample. In certain embodiments, the test strip can include a working electrode and a counter electrode and the electrode 10 described herein can be present as the working electrode, the counter electrode, or both.

According to still other embodiments, the electrode 10 may have a particular thickness. For example, the electrode 10 may have a thickness of at least about 15 nm, such as, at least about 18 nm, at least about 20 nm, at least about 23 nm, at least about 25 nm, at least about 28 nm or even at least about 30 nm. According to still other embodiments, the electrode 10 may have a thickness of not greater than about 60 nm, such as, not greater than about 57 nm, not greater than about 55 nm, not greater than about 52 nm, not greater than about 50 nm, not greater than about 47 nm, not greater than about 45 nm, not greater than about 42 nm or even not greater than about 40 nm. It will be appreciated that the electrode 10 may have a thickness within a range between any of the minimum and maximum values noted above. It will be further appreciated that the electrode 10 may have a thickness of any value between any of the minimum and maximum values noted above.

According to certain embodiments, the substrate 20 may be constructed out of any material suitable for the substrate of an electrode. According to certain embodiments, the material forming the substrate 20 can contain a polymer, a flexible polymer, or a transparent polymer. Suitable polymers can include, for example, polycarbonate, polyacrylate, polyester, polyethylene terephthalate (PET), polyethylene naphthalate (PEN), cellulose triacetated (TCA or TAC), polyurethane, or any combination thereof. In particular embodiments, the substrate can be a glass substrate, such as a transparent glass substrate.

According to yet other embodiments, the substrate 20 may have a particular thickness suitable for an electrode. For example, the substrate 20 may have a thickness of at least about 1 micron, such as, at least about 5 microns, at least about 10 microns, at least about 15 microns, at least about 20 microns, at least about 25 microns, at least about 30 microns, at least about 35 microns, at least about 40 microns, at least about 45 microns or even at least about 50 microns. According to still other embodiments, the substrate 20 may have a thickness of not greater than about 1,000 microns, such as, not greater than about 750 microns, not greater than about 500 microns, not greater than about 400 microns or even not greater than about 300 microns. It will be appreciated that the substrate 20 may have a thickness within a range between any of the minimum and maximum values noted above. It will be further appreciated that the substrate 20 may have a thickness of any value between any of the minimum and maximum values noted above. For example, the substrate can have a thickness in a range of from about 20 microns to about 500 microns or from about 40 microns to about 300 microns. In very particular embodiments, the substrate can have a thickness in a range of from about 100 microns to about 300 microns.

According to still other embodiments and as shown in FIG. 1, a surface 22 of the substrate 20 that is adjacent to adhesive layer 25 can be treated to improve adhesion between the substrate 20 and adhesive layer 25. For example, treating the surface 22 of the substrate 20 can include a laser treatment, a plasma treatment or a chemical treatment of the surface 22 of the substrate 20.

According to yet other embodiments, the surface 22 of the substrate 20 may have a particular root mean squared surface roughness (Rᵣₘₛ). For example, the surface 22 may have a root mean squared surface roughness of at least about 1 nm, such as, at least about 2 nm, at least about 3 nm, at least about 4 nm, at least about 5 nm, at least about 10 nm, at least about 50 nm or even at least about 100 nm. According to yet other embodiments, the surface 22 may have a root mean squared surface roughness of not greater than about 200 nm, such as, not greater than about 180 nm, not greater than about 160 nm, not greater than about 140 nm or even not greater than about 120 nm. It will be appreciated that the surface 22 may have a root mean squared surface roughness of any value within a range between any of the minimum and maximum values noted above. It will be further appreciated that the surface 22 may have a root mean squared surface roughness of any value between any of the minimum and maximum values noted above.

According to particular embodiments, the first layer 30 may contain one or more of the following materials and the one or more materials contained in the first layer 30 can have one or more, or even all, of the following characteristics.

According to certain embodiments, the first layer 30 may be referred to as a film. According to yet other embodiment, the first layer 30 may be referred to as a thin film.

According to still other embodiments, the first layer 30 may include silver (Ag), copper (Cu), ruthenium (Ru) or combinations thereof. According to still other embodiments, the first layer 30 may consist essentially of Ag. As used herein the phrase “consists essentially” refers to including at least 95 atomic % of a given material. According to still other embodiments, the first layer 30 may consist of Ag. According to still other embodiments, the first layer 30 may be a silver layer. According to still other embodiments, the first layer 30 may consist essentially of Cu. According to still other embodiments, the first layer 30 may consist of Cu. According to still other embodiments, the first layer 30 may be a copper layer. According to still other embodiments, the first layer 30 may consist essentially of Ru. According to still other embodiments, the first layer 30 may consist of Ru. According to still other embodiments, the first layer 30 may be a ruthenium layer. According to still other embodiments, the first layer 30 may consist of a combination of any two of Ag, Cu and Ru. According to yet other embodiments, the first layer 30 may consist of a combination of Ag, Cu and Ru.

According to still other embodiments, the first layer 30 may have a particular thickness. For example, the first layer 30 may have a thickness of at least about 5 nm, such as, at least about 8 nm, at least about 10 nm, at least about 13 nm, at least about 15 nm, at least about 18 nm or even at least about 20 nm. According to still other embodiments, the first layer 30 may have a thickness of not greater than about 30 nm, such as, not greater than about 28 nm, not greater than about 25 nm, not greater than about 23 nm or even not greater than about 21 nm. It will be appreciated that the thickness of the first layer 30 may be any value within a range between any of the minimum and maximum values noted above. It will be further appreciated that the thickness of the first layer 30 may be any value between any of the minimum and maximum values noted above.

According to yet other embodiments, the first layer 30 may contain substantially no carbon. According to yet other embodiment, the first layer 30 may contain substantially no carbon in the form of graphite.

According to yet other embodiments, the first layer 30 may contain substantially no tin oxide. According to yet other embodiment, the first layer 30 may contain substantially no tin oxide.

According to yet other embodiments, the first layer 30 may have a particular resistivity. For example, the first layer 30 may have a resistivity of at least about 2×10⁻⁶ Ohm·cm, such as, at least about 3×10⁻⁶ Ohm·cm, at least about 4×10⁻⁶ Ohm·cm, at least about 5×10⁻⁶ Ohm·cm, at least about 8×10⁻⁶ Ohm·cm, at least about 10×10⁻⁶ Ohm·cm, at least about 13×10⁻⁶ Ohm·cm, at least about 15×10⁻⁶ Ohm·cm, at least about 18×10⁻⁶ Ohm·cm or even at least about 20×10⁻⁶ Ohm·cm. According to yet other embodiments, the first layer 30 may have resistivity of not greater than about 35×10⁻⁶ Ohm·cm, such as, not greater than about 33×10⁻⁶ Ohm·cm, not greater than about 30×10⁻⁶ Ohm·cm, not greater than about 28×10⁻⁶ Ohm·cm, not greater than about 25×10⁻⁶ Ohm·cm, not greater than about 23×10⁻⁶ Ohm·cm or even not greater than about 21×10⁻⁶ Ohm·cm. It will be appreciated that the resistivity of the first layer 30 may be any value within a range between any of the minimum and maximum values noted above. It will be further appreciated that the resistivity of the first layer 30 may be any value between any of the minimum and maximum values noted above.

According to certain embodiments, the second layer 40 may be referred to as a film. According to yet other embodiment, the second layer 40 may be referred to as a thin film.

According to still other embodiments, the second layer 40 may include gold (Au). According to still other embodiments, the second layer 40 may consist essentially of Au. According to still other embodiments, the second layer 40 may consist of Au. According to still other embodiments, the second layer 40 may be a gold layer.

According to still other embodiments, the second layer 40 may have a particular thickness. For example, the second layer 40 may have a thickness of at least about 5 nm, such as, at least about 8 nm, at least about 10 nm, at least about 13 nm or even at least about 15 nm. According to still other embodiments, the second layer 40 may have a thickness of not greater than about 25 nm, such as, not greater than about 23 nm, not greater than about 20 nm or even not greater than about 18 nm. It will be appreciated that the thickness of the second layer 40 may be any value within a range between any of the minimum and maximum values noted above. It will be further appreciated that the thickness of the second layer 40 may be any value between any of the minimum and maximum values noted above.

According to still other embodiments, when the second layer 40 may have a particular sheet resistance. For example, the second layer 40 may have a sheet resistance of not greater than about 3×10⁻⁵ Ohm·cm, such as, not greater than about 2×10⁻⁵ Ohm·cm, not greater than about 1×10⁻⁵ Ohm·cm, not greater than about 9×10⁻⁶ Ohm·cm, not greater than about 8×10⁻⁶ Ohm·cm, not greater than about 7×10⁻⁶ Ohm·cm, or even not greater than about 6×10⁻⁶ Ohm·cm. According to still other embodiments, the second layer 40 may have a sheet resistance of at least about 2×10⁻⁶ Ohm·cm, at least about 3×10⁻⁶ Ohm·cm, at least about 4×10⁻⁶ Ohm·cm, and at least about 5×10⁻⁶ Ohm·cm. It will be appreciated that the sheet resistance of the second layer 40 may be any value within a range between any of the minimum and maximum values noted above. It will be further appreciated that the sheet resistance of the second layer 40 may be any value between any of the minimum and maximum values noted above.

According to still other embodiments, the electrode 10 may have a particular layer thickness ratio L1_{TH}/L2_{TH}, where L1_{TH} is the thickness of the first layer 30 and L2_{TH} is the thickness of the second layer 40. For example, the electrode 10 may have a layer thickness ratio L1_{TH}/L2_{TH} of at least about 0.7, such as, at least about 0.8, at least about 0.9, at least about 1.0, at least about 1.1, at least about 1.2, at least about 1.3, at least about 1.4, at least about 1.5, at least about 1.6, at least about 1.7, at least about 1.8, at least about 1.9, at least about 2.0, at least about 2.2, at least about 2.4, at least about 2.6, at least about 2.8, at least about 3.0, at least about 3.2, at least about 3.4, at least about 3.6, at least about 3.8 or even at least about 4.0. According to still other embodiments, the electrode 10 may have a layer thickness ratio L1_{TH}/L2_{TH} of not greater than about 5, such as, not greater than about 4.5 or even not greater than about 4.0. It will be appreciated that the layer thickness ratio L1_{TH}/L2_{TH} of the electrode 10 may be any value within a range between any of the minimum and maximum values noted above. It will be further appreciated that the layer thickness ratio L1_{TH}/L2_{TH} of the electrode 10 may be any value between any of the minimum and maximum values noted above.

According to still other embodiments, when the electrode 10 may have a particular sheet resistance. For example, the electrode 10 may have a sheet resistance of at least about 0.5 Ohm/sq, such as, at least about 0.8 Ohm/sq, at least about 1.0 Ohm/sq, at least about 1.2 Ohm/sq or even at least about 1.4 Ohm/sq. According to still other embodiments, the electrode 10 may have a sheet resistance of not greater than about 30 Ohm/sq, such as, not greater than about 25 Ohm/sq, not greater than about 20 Ohm/sq, not greater than about 15 Ohm/sq or even not greater than about 10. It will be appreciated that the sheet resistance of the electrode 10 may be any value within a range between any of the minimum and maximum values noted above. It will be further appreciated that the sheet resistance of the electrode 10 may be any value between any of the minimum and maximum values noted above.

According to certain embodiments, the adhesive layer 25 may be referred to as a film. According to yet other embodiment, the adhesive layer 25 may be referred to as a thin film.

According to still other embodiments, the adhesive layer 25 may include NiCr. According to still other embodiments, the adhesive layer 25 may consist essentially of NiCr. According to still other embodiments, the adhesive layer 25 may consist of NiCr. According to still other embodiments, the adhesive layer 25 may be a NiCr adhesive layer.

According to yet other embodiments, the NiCr of the adhesive layer 25 may be a NiCr alloy. According to still other embodiments, the NiCr alloy may have a particular content of Ni for a total weight of the NiCr alloy. For example, the NiCr alloy may have about 80 wt % Ni. According to still other embodiments, the NiCr alloy may have a particular content of Cr for a total weight of the NiCr alloy. For example, the NiCr alloy may have about 20 wt % Cr.

According to still other embodiments, the adhesive layer 25 may have a particular thickness. For example, the adhesive layer 25 may have a thickness of at least about 1 nm, such as, at least about 1.5 nm, at least about 2.0 nm or even at least about 2.5 nm. According to still other embodiments, the adhesive layer 25 may have a thickness of not greater than about 5 nm, such as, not greater than about 4.5 nm, not greater than about 4.0 nm or even not greater than about 3.5 nm. It will be appreciated that the thickness of the adhesive layer 25 may be any value within a range between any of the minimum and maximum values noted above. It will be further appreciated that the thickness of the adhesive layer 25 may be any value between any of the minimum and maximum values noted above.

Also described herein are electrochemical sensors. According to particular embodiments, the electrochemical sensors may be adapted to detect the presence of, and/or measure the concentration of, an analyte by way of electrochemical oxidation and reduction reactions within the sensor. These reactions can be transduced to an electrical signal that can be correlated to an amount or concentration of the analyte. In certain embodiments, the electrochemical sensor can be a biosensor test strip.

According to still other embodiments, the test strip may include a base substrate, a spacing layer, a covering layer, or any combination thereof. The base substrate can include an electrode system and the electrode system can include a set of measuring electrodes, e.g., at least a working electrode and a counter electrode, within a sample-receiving chamber. According to particular embodiments, one or more of the electrodes in the electrode system can include an electrode as described herein.

Further, in particular embodiments, the spacing layer of the test strip can define a sample-receiving chamber extending between the base substrate and the covering layer. The sample-receiving chamber can be adapted such that a sample fluid can enter a chamber and be placed in electrolytic contact with both the working electrode and the counter electrode. Such contact can allow electrical current to flow between the measuring electrodes to affect the electrooxidation or electroreduction of the analyte. In very particular embodiments, the sample fluid can be a blood sample, such as a human blood sample, and the sensor can be adapted to measure the glucose level in such a sample.

Moreover, a suitable reagent system can overlie at least a portion of the electrodes or electrode pairs within the sample-receiving chamber. The reagent system can include additives to enhance the reagent properties or characteristics. For example, additives can include materials to facilitate the placement of the reagent composition onto the test strip and to improve its adherence to the strip, or for increasing the rate of hydration of the reagent composition by the sample fluid. Additionally, the additives can include components selected to enhance the physical properties of the resulting dried reagent layer, and the uptake of a liquid test sample for analysis. In certain embodiments, the additives can include thickeners, viscosity modulators, film formers, stabilizers, buffers, detergents, gelling agents, fillers, film openers, coloring agents, agents endowing thixotropy, or any combination thereof.

In further embodiments, the covering layer can be adapted to form a top surface of the sample-receiving chamber. Moreover, the covering layer can be adapted to provide a hydrophilic surface to aid in acquisition of the test sample. In particular embodiments, the covering layer can define a vent opening that allows air to escape from the interior of the chamber as the sample fluid enters and moves into the sample-receiving chamber.

According to certain embodiments, an electrode as described herein can be formed according to any appropriate method. In general, forming the electrode includes providing a substrate as described herein, depositing the first layer as described herein, and depositing the second layer as described herein. For example, the first layer can be deposited over the substrate and the second layer can be deposited over the first layer. In certain embodiments, the first layer can be deposited directly onto the substrate. In still other embodiments, the second layer can be deposited directly onto the first layer.

According to still other embodiments, the method may include depositing one or more of the layers by physical vapor deposition, such as sputtering or even magnetron sputtering. According to certain embodiments, the first layer 30 may be deposited with or without annealing. In certain embodiments, the first layer 30 may be deposited without annealing. The materials used for forming the first layer 30 may have a standard deposition rate.

According to yet other embodiments, the first layer 30 and the second layer 40 may be deposited by roll-to-roll processing. Roll-to-roll processing refers to a process of applying coatings starting with a roll of a flexible material and re-reeling after the process to create an output roll. In certain embodiments, the roll-to-roll process can include depositing the first and second layers using two cathodes, such as simultaneously using two cathodes.

According to still other embodiments, the first layer 30 may be deposited at a particular pressure. For examples, the first layer 30 may be deposited at a pressure of not greater than about 10 mTorr, such as, not greater than about 9 mTorr or even not greater than about 8 mTorr. According to particular embodiments, the first layer 30 may be deposited at a pressure of at least about 1 mTorr, at least about 2 mTorr, or even at least about 3 mTorr. It will be appreciated that the first layer 30 may be deposited at a pressure of any value within a range between any of the minimum and maximum values noted above. It will be further appreciated that the first layer 30 may be deposited at a pressure of any value between any of the minimum and maximum values noted above.

According to still other embodiments, the second layer 40 may be deposited at a particular pressure. For examples, the second layer 40 may be deposited at a pressure of not greater than about 10 mTorr, such as, not greater than about 9 mTorr or even not greater than about 8 mTorr. According to particular embodiments, the second layer 40 may be deposited at a pressure of at least about 5 mTorr, at least about 6 mTorr, or even at least about 7 mTorr. It will be appreciated that the second layer 40 may be deposited at a pressure of any value within a range between any of the minimum and maximum values noted above. It will be further appreciated that the second layer 40 may be deposited at a pressure of any value between any of the minimum and maximum values noted above.

Many different aspects and embodiments are possible. Some of those aspects and embodiments are described below. After reading this specification, skilled artisans will appreciate that those aspects and embodiments are only illustrative and do not limit the scope of the present invention. Embodiments can be in accordance with any one or more of the items as listed below.

### Embodiment 1

An electrode comprising: a substrate; an adhesive layer; a first layer comprising Ag, Cu, Ru or a combination thereof; and a second layer comprising Au, wherein the second layer has a thickness of not greater than about 25 nm, wherein the adhesive layer is disposed between the substrate and the first layer, and wherein the first layer is disposed between the adhesive layer and the second layer.

### Embodiment 2

An electrode comprising: a substrate; an adhesive layer; a first layer comprising at least one of Ag, Cu, Ru or a combination thereof; and a second layer comprising Au, wherein the first layer has a thickness of at least about 5 nm, wherein the adhesive layer is disposed between the substrate and the first layer, and wherein the first layer is disposed between the adhesive layer and the second layer.

### Embodiment 3

An electrode comprising: a substrate; an adhesive layer; a first layer comprising at least one of Ag, Cu, Ru or a combination thereof; and a second layer comprising Au, wherein the electrode comprises a layer thickness ratio L1_{TH}/L2_{TH} of at least about 0.7, where L1_{TH} is the thickness of the first layer and L2_{TH} is the thickness of the second layer, wherein the adhesive layer is disposed between the substrate and the first layer, and wherein the first layer is disposed between the adhesive layer and the second layer.

### Embodiment 4

An electrode comprising: a substrate; an adhesive layer; a first layer comprising at least one of Ag, Cu, Ru or a combination thereof; and a second layer comprising Au, wherein the first layer has a thickness of at least about 5 nm and not greater than about 30 nm, wherein the second layer has a thickness of at least about 5 nm and not greater than about 25 nm, wherein the adhesive layer is disposed between the substrate and the first layer, and wherein the first layer is disposed between the adhesive layer and the second layer.

### Embodiment 5

A biosensor test strip comprising: an electrode system that includes an electrode, the electrode comprising: a substrate; an adhesive layer; a first layer comprising at least one of Ag, Cu or a combination thereof; and a second layer comprising Au, wherein the electrode comprises a layer thickness ratio L1_{TH}/L2_{TH} of at least about 0.7, where L1_{TH} is the thickness of the first layer and L2_{TH} is the thickness of the second layer, wherein the adhesive layer is disposed between the substrate and the first layer, and wherein the first layer is disposed between the adhesive layer and the second layer.

### Embodiment 6

A method of forming an electrode, comprising: providing a substrate; depositing an adhesive layer on the substrate; depositing a first layer over the adhesive layer, wherein the at least one of Ag, Cu, R u or a combination thereof; and depositing a second layer over the first layer, wherein the second layer comprises Au, wherein the electrode comprises a layer thickness ratio L1_{TH}/L2_{TH} of at least about 0.7, where L1_{TH} is the thickness of the first layer and L2_{TH} is the thickness of the second layer.

### Embodiment 7

The electrode, biosensor test strip, composite and method of any one of embodiments 1, 2, and 4, wherein the electrode further comprises a layer thickness ratio L1_{TH}/L2_{TH} of at least about 0.7, where L1_{TH} is the thickness of the first layer and L2_{TH} is the thickness of the second layer.

### Embodiment 8

The electrode, biosensor test strip, composite and method of any one of embodiments 3, 5, 6, and 7, wherein the electrode further comprises a layer thickness ratio L1_{TH}/L2_{TH} of at least about 0.8, where L1_{TH} is the thickness of the first layer and L2_{TH} is the thickness of the second layer, at least about 0.9, at least about 1.0, at least about 1.1, at least about 1.2, at least about 1.3, at least about 1.4, at least about 1.5, at least about 1.6, at least about 1.7, at least about 1.8, at least about 1.9, at least about 2.0, at least about 2.2, at least about 2.4, at least about 2.6, at least about 2.8, at least about 3.0, at least about 3.2, at least about 3.4, at least about 3.6, at least about 3.8, and at least about 4.0.

### Embodiment 9

The electrode, biosensor test strip, composite and method of any one of embodiments 3, 5, 6, and 7, wherein the electrode further comprises a layer thickness ratio L1_{TH}/L2_{TH} of not greater than about 5, where L1_{TH} is the thickness of the first layer and L2_{TH} is the thickness of the second layer, not greater than about 4.5, and not greater than about 4.0.

### Embodiment 10

The electrode, biosensor test strip, composite and method of any one of the previous embodiments, wherein the electrode has a sheet resistance of at least about 0.5 Ohm/sq.

### Embodiment 11

The electrode, biosensor test strip, composite and method of any one of embodiments 1, 2, 3, 4, 5, and 6, wherein the electrode has a sheet resistance of not greater than about 35 Ohm/sq.

### Embodiment 12

The electrode, biosensor test strip, composite and method of any one of embodiments 1, 2, 3, 4, 5, and 6, wherein the electrode has a thickness of at least about 7 nm, at least about 8 nm, at least about 9 nm, at least about 10 nm, at least about 12 nm, at least about 14 nm, at least about 16 nm, at least about 18 nm, at least about 20 nm, at least about 22 nm, at least about 24 nm, at least about 26 nm, at least about 28 nm, at least about 30 nm, at least about 35 nm, and at least about 40 nm.

### Embodiment 13

The electrode, biosensor test strip, composite and method of any one of embodiments 1, 2, 3, 4, 5, and 6, wherein the electrode has a thickness of not greater than about 60 nm, not greater than about 59 nm, not greater than about 58 nm, not greater than about 57 nm, not greater than about 56 nm, not greater than about 55 nm, not greater than about 54 nm, not greater than about 53 nm, not greater than about 52 nm, not greater than about 51 nm, not greater than about 50 nm, not greater than about 48 nm, not greater than about 46 nm, not greater than about 44 nm, and not greater than about 42 nm.

### Embodiment 14

The electrode, biosensor test strip, composite and method of any one of embodiments 1, 2, 3, 4, 5, and 6, wherein the first layer consists of Ag.

### Embodiment 15

The electrode, biosensor test strip, composite and method of any one of embodiments 1, 2, 3, 4, 5, and 6, wherein the first layer is an Ag layer.

### Embodiment 16

The electrode, biosensor test strip, composite and method of any one of embodiments 1, 2, 3, 4, 5, and 6, wherein the first layer consists of Cu.

### Embodiment 17

The electrode, biosensor test strip, composite and method of any one of embodiments 1, 2, 3, 4, 5, and 6, wherein the first layer is a Cu layer.

### Embodiment 18

The electrode, biosensor test strip, composite and method of any one of embodiments 1, 2, 3, 4, 5, and 6, wherein the first layer consists of Ru.

### Embodiment 19

The electrode, biosensor test strip, composite and method of any one of embodiments 1, 2, 3, 4, 5, and 6, wherein the first layer is a Ru layer.

### Embodiment 20

The electrode, biosensor test strip, composite and method of any one of embodiments 1, 2, 3, 4, 5, and 6, wherein the first layer has a thickness of at least about 5 nm, at least about 6 nm, at least about 7 nm, at least about 8 nm, at least about 9 nm, at least about 10 nm, at least about at least about 12 nm, at least about 15 nm, at least about 17 nm, at least about 20 nm, at least about 22 nm, and at least about 25 nm.

### Embodiment 21

The electrode, biosensor test strip, composite and method of any one of embodiments 1, 2, 3, 4, 5, and 6, wherein the first layer has a thickness of not greater than about 30 nm, not greater than about 29 nm, not greater than about 28 nm, not greater than about 27 nm, and not greater than about 26 nm.

### Embodiment 22

The electrode, biosensor test strip, composite and method of any one of embodiments 1, 2, 3, 4, 5, and 6, wherein the first layer has a resistivity of at least about 2×10⁻⁶ Ohm·cm.

### Embodiment 23

The electrode, biosensor test strip, composite and method of any one of embodiments 1, 2, 3, 4, 5, and 6, wherein the first layer has a resistivity of not greater than about 35×10⁻⁶ Ohm·cm.

### Embodiment 24

The electrode, biosensor test strip, composite and method of any one of embodiments 1, 2, 3, 4, 5, and 6, wherein the second layer consists of Au.

### Embodiment 25

The electrode, biosensor test strip, composite and method of any one of embodiments 1, 2, 3, 4, 5, and 6, wherein the second layer is an Au layer.

### Embodiment 26

The electrode, biosensor test strip, composite and method of any one of embodiments 1, 2, 3, 4, 5, and 6, wherein the second layer has a thickness of at least about 5 nm, at least about 6 nm, at least about 7 nm, at least about 8 nm, at least about 9 nm, at least about 10 nm, at least about 11 nm, at least about 12 nm, at least about 13 nm, at least about 14 nm, at least about 15 nm, at least about 16 nm, at least about 17 nm, at least about 18 nm, at least about 19 nm, and at least about 20 nm.

### Embodiment 27

The electrode, biosensor test strip, composite and method of any one of embodiments 1, 2, 3, 4, 5, and 6, wherein the second layer has a thickness of not greater than about 25 nm, not greater than about 24 nm, not greater than about 23 nm, not greater than about 22 nm, and not greater than about 21 nm.

### Embodiment 28

The electrode, biosensor test strip, composite and method of any one of embodiments 1, 2, 3, 4, 5, and 6, wherein the adhesive layer comprises NiCr.

### Embodiment 29

The electrode, biosensor test strip, composite and method of embodiment 28, wherein the NiCr is a NiCr alloy, wherein the NiCr alloy has 80 wt. % Ni for a total weight the NiCr alloy, wherein the NiCr alloy has 20 wt. % Cr for a total weight of the NiCr alloy.

### Embodiment 30

The electrode, biosensor test strip, composite and method of any one of embodiments 1, 2, 3, 4, 5, and 6, wherein the adhesive layer consists of NiCr.

### Embodiment 31

The electrode, biosensor test strip, composite and method of embodiment 30, wherein the NiCr is a NiCr alloy, wherein the NiCr alloy has 80 wt. % Ni for a total weight the NiCr alloy, wherein the NiCr alloy has 20 wt. % Cr for a total weight of the NiCr alloy.

### Embodiment 32

The electrode, biosensor test strip, composite and method of any one of embodiments 1, 2, 3, 4, 5, and 6, wherein the adhesive layer is a NiCr adhesive layer.

### Embodiment 33

The electrode, biosensor test strip, composite and method of embodiment 32, wherein the NiCr is a NiCr alloy, wherein the NiCr alloy has 80 wt. % Ni for a total weight the NiCr alloy, wherein the NiCr alloy has 20 wt. % Cr for a total weight of the NiCr alloy.

### Embodiment 34

The electrode, biosensor test strip, composite and method of any one of embodiments 1, 2, 3, 4, 5, and 6, wherein the first layer does not contain tin oxide.

### Embodiment 35

The electrode, biosensor test strip, composite and method of any one of embodiments 1, 2, 3, 4, 5, and 6, wherein the first layer does not contain carbon.

### Embodiment 36

The electrode, biosensor test strip, composite and method of any one of embodiments 1, 2, 3, 4, 5, and 6, wherein the second layer is a film or a thin film.

### Embodiment 37

The electrode, biosensor test strip, composite and method of any one of embodiments 1, 2, 3, 4, 5, and 6, wherein the metal of the first layer has a purity of from 60% to 100%, from 65% to 95%, from 70% to 90%, and from 75% to 85%.

### Embodiment 38

The electrode, biosensor test strip, composite and method of any one of embodiments 1, 2, 3, 4, 5, and 6, wherein the metal of the second layer has a purity of from 60% to 100%, from 65% to 95%, from 70% to 90%, and from 75% to 85%.

### Embodiment 39

The electrode, biosensor test strip, composite and method of any of embodiments 1, 2, 3, 4, 5, and 6, wherein the second layer has a resistivity of not greater than about 3.5×10⁻⁵ Ohm·cm, not greater than about 2×10⁻⁵ Ohm·cm, not greater than about 1×10⁻⁵ Ohm·cm, not greater than about 9×10⁻⁶ Ohm·cm, not greater than about 8×10⁻⁶ Ohm·cm and not greater than about 7×10⁻⁶ Ohm·cm, and not greater than about 6×10⁻⁶ Ohm·cm.

### Embodiment 40

The electrode, biosensor test strip, composite and method of any of embodiments 1, 2, 3, 4, 5, and 6, wherein the second layer has a resistivity of at least about 2×10⁻⁶ Ohm·cm, at least about 3×10⁻⁶ Ohm·cm, at least about 4×10⁻⁶ Ohm·cm, and at least about 5×10⁻⁶ Ohm·cm.

### Embodiment 41

The electrode, biosensor test strip, composite and method of any one of embodiments 1, 2, 3, 4, 5, and 6, wherein the metal of the second layer has a purity of from 60% to 100%, from 65% to 95%, from 70% to 90%, and from 75% to 85%.

### Embodiment 42

The electrode, biosensor test strip, composite and method of any one of embodiments 1, 2, 3, 4, 5, and 6, wherein the substrate comprises polycarbonate, polyacrylate, polyester, polyethylene terephthalate (PET), polyethylene naphthalate (PEN), cellulose triacetated (TCA or TAC), polyurethane and any combination thereof.

### Embodiment 43

The electrode, biosensor test strip, composite and method of any one of embodiments 1, 2, 3, 4, 5, and 6, wherein the substrate comprises polyethylene terephthalate (PET).

### Embodiment 44

The electrode, biosensor test strip, composite and method of any one of embodiments 1, 2, 3, 4, 5, and 6, wherein the substrate has a thickness of at least about 50 microns, at least about 45 microns, at least about 40 microns, at least about 35 microns, at least about 30 microns, at least about 25 microns, at least about 20 microns, at least about 15 microns, at least about 10 microns, at least about 5 microns, and at least about 1 micron.

### Embodiment 45

The electrode, biosensor test strip, composite and method of any one of embodiments 1, 2, 3, 4, 5, and 6, wherein the substrate has a thickness of not greater than about 500 microns, not greater than about 200 microns, not greater than about 100 microns, not greater than about 90 microns, not greater than about 80 microns, not greater than about 75 microns, not greater than about 70 microns, not greater than about 65 microns, not greater than about 60 microns, not greater than about 55 microns, and not greater than about 50 microns.

### Embodiment 46

The electrode, biosensor test strip, composite and method of any one of embodiments 1, 2, 3, 4, 5, and 6, wherein the adhesive layer directly contacts the substrate, the first layer directly contacts the adhesive layer and the second layer directly contacts the first layer.

### Embodiment 47

The electrode, biosensor test strip, composite and method of any one of embodiments 1, 2, 3, 4, 5, and 6, wherein the electrode further comprises a layer comprising a chemical solution.

### Embodiment 48

The electrode, biosensor test strip, composite and method of any one of embodiments 1, 2, 3, 4, 5, and 6, wherein the electrode further comprises an enzyme, a mediator and any combination thereof.

### Embodiment 49

The electrode, biosensor test strip, composite and method of any one of embodiments 1, 2, 3, 4, 5, and 6, wherein the (first) electrode is reactive to glucose.

### Embodiment 50

The electrode, biosensor test strip, composite and method of any one of embodiments 1, 2, 3, 4, 5, and 6, wherein the electrode is a working electrode.

### Embodiment 51

The biosensor test strip of embodiment 5, wherein the electrode system further comprises a counter electrode.

### Embodiment 52

The method of embodiment 6, wherein the first layer is deposited directly onto the substrate, the layer comprising the metal is deposited directly onto an adhesive layer.

### Embodiment 53

The method of embodiment 6, wherein the first layer is deposited by sputtering, the second layer is deposited by sputtering or both.

### Embodiment 54

The method of embodiment 6, wherein the adhesive layer, the first layer and the second layer are deposited simultaneously using a roll-to-roll coater.

### Embodiment 55

The method of embodiment 6, wherein the first layer is deposited without annealing.

### Embodiment 56

The method of embodiment 6, wherein the second layer is deposited at a pressure of not greater than about 10 mTorr, not greater than about 9 mTorr, and not greater than about 8 mTorr.

### Embodiment 57

The method of embodiment 6, wherein the second layer is deposited at a pressure of at least about 5 mTorr, at least about 6 mTorr, and at least about 7 mTorr.

### EXAMPLES

### Example 1

Five sample electrodes S1-S5 were formed by depositing an adhesive layer of NiCr, a silver (Ag) layer, and a gold (Au) layer on a PET substrate. Sample electrodes S1-S5 have a stack configuration of PET/NiCr/Ag/Au. The thicknesses of the NiCr layer, the silver layer and the gold layer in each sample electrode S1-S5 are listed in Table 1.

A reference electrode and comparative sample electrodes CS1-CS3 were formed for performance comparison to the sample electrodes S1-S5. The reference electrode was formed by depositing a gold layer on a PET substrate. Comparative sample electrode CS1 was formed by depositing an adhesive layer of Ti and a silver layer on a PET substrate. Comparative sample electrode CS1 has a configuration of PET/Ti/Ag. Comparative sample electrode CS2 was formed by depositing an adhesive layer of Ti, a silver layer and a gold layer on a PET substrate. Comparative sample electrode CS2 has a stack configuration of PET/Ti/Ag/Au. Comparative sample electrode CS3 was formed by depositing an adhesive layer of NiCr, a dielectric layer of AZO, a silver layer and a gold layer on a PET substrate. Comparative sample electrode CS3 has a stack configuration of PET/Ti/AZO/Ag/Au. The thicknesses of the layers in the reference electrode and each comparative sample electrode CS1-CS3 are listed in Table 1.

Each sample electrode S1-S5 and comparative sample electrodes CS1-CS4 were measured to determine the sheet resistance of the electrode. The measurements were taken according to an electromagnetic non-contact method using a Nagy apparatus. The results are reported in Table 1 below.

TABLE 1

| | | | | | | Resistivity - |
|---|---|---|---|---|---|---|
| | NiCr | Ti | AZO | Ag | Au | R/Sq |
| Samples | (nm) | (nm) | (nm) | (nm) | (nm) | (Ohm/Sq) |
| REF | — | — | — | — | 50 | 0.94 |
| CS1 | — | 5 | — | 20 | — | 2.38 |
| CS2 | — | 5 | — | 20 | 15 | 1.63 |
| CS3 | 5 | — | 5 | 20 | 15 | 1.54 |
| S1 | 5 | — | — | 20 | 8 | 1.74 |
| S2 | 5 | — | — | 20 | 15 | 1.34 |
| S3 | 5 | — | — | 20 | 25 | 1.25 |
| S4 | 5 | — | — | 30 | 15 | 1.32 |
| S5 | 5 | — | — | 30 | 25 | 1.06 |

Table 1 shows R/Sq values of different electrodes made of pure gold, silver and silver covered by gold, deposited on Ti or NiCr adhesive layers. In particular, the R/Sq value for S3 is similar to the R/Sq value of the references electrode. The R/Sq values for the other sample electrodes are significantly higher than the R/Sq value of the references electrode. The R/sq values for CS3 and S2 are similar.

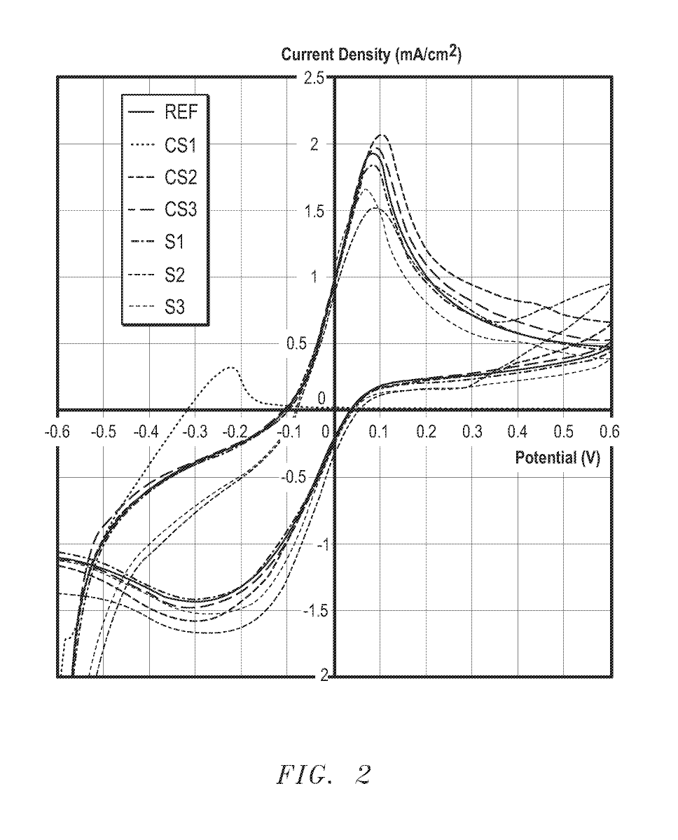

FIG. 2 includes cyclic voltammetry curves for each sample electrode S1-S5, the reference electrode and each comparative sample electrode CS1-CS3.

Note that not all of the activities described above in the general description or the examples are required, that a portion of a specific activity can not be required, and that one or more further activities can be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any features that can cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments can also be provided in combination in a single embodiment, and conversely, various features that are, for brevity, described in the context of a single embodiment, can also be provided separately or in any subcombination. Further, reference to values stated in ranges includes each and every value within that range. Many other embodiments can be apparent to skilled artisans only after reading this specification. Other embodiments can be used and derived from the disclosure, such that a structural substitution, logical substitution, or another change can be made without departing from the scope of the disclosure. Accordingly, the disclosure is to be regarded as illustrative rather than restrictive.

What is claimed is:

1. An electrode comprising:
a substrate;
an adhesive layer;
a first layer comprising Ag, Cu, Ru or a combination thereof; and
a second layer comprising Au,
wherein the second layer has a thickness of not greater than about 25 nm,
wherein the adhesive layer is disposed between the substrate and the first layer, and
wherein the first layer is disposed between the adhesive layer and the second layer.

2. The electrode of claim 1, wherein the electrode further comprises a layer thickness ratio L1_{TH}/L2_{TH} of at least about 0.7, where L1_{TH} is the thickness of the first layer and L2_{TH} is the thickness of the second layer.

3. The electrode of claim 1, wherein the electrode has a sheet resistance of at least about 0.5 Ohm/sq.

4. The electrode of claim 1, wherein the electrode has a sheet resistance of not greater than about 35 Ohm/sq.

5. The electrode of claim 1, wherein the electrode has a thickness of at least about 7 nm and not greater than about 60 nm.

6. The electrode of claim 1, wherein the first layer consists of Ag.

7. The electrode of claim 1, wherein the first layer consists of Cu.

8. The electrode of claim 1, wherein the first layer consists of Ru.

9. The electrode of claim 1, wherein the first layer has a resistivity of at least about 2×10⁻⁶ Ohm·cm.

10. The electrode of claim 1, wherein the first layer has a resistivity of not greater than about 30×10⁻⁶ Ohm·cm.

11. The electrode of claim 1, wherein the adhesive layer comprises NiCr.

12. The electrode of claim 1, wherein the first layer does not contain tin oxide.

13. An electrode comprising:
a substrate;
an adhesive layer;
a first layer comprising at least one of Ag, Cu, Ru or a combination thereof; and
a second layer comprising Au,
wherein the first layer has a thickness of at least about 5 nm,
wherein the adhesive layer is disposed between the substrate and the first layer, and
wherein the first layer is disposed between the adhesive layer and the second layer.

14. The electrode of claim 13, wherein the electrode further comprises a layer thickness ratio L1_{TH}/L2_{TH} of at least about 0.7, where L1_{TH} is the thickness of the first layer and L2_{TH} is the thickness of the second layer.

15. The electrode of claim 13, wherein the electrode has a sheet resistance of at least about 0.5 Ohm/sq.

16. The electrode of claim 13, wherein the electrode has a sheet resistance of not greater than about 35 Ohm/sq.

17. The electrode of claim 13, wherein the first layer consists of Ag.

18. The electrode of claim 13, wherein the first layer consists of Cu.

19. The electrode of claim 13, wherein the first layer consists of Ru.

20. An electrode comprising:
a substrate;
an adhesive layer;
a first layer comprising at least one of Ag, Cu, Ru or a combination thereof; and
a second layer comprising Au,
wherein the electrode comprises a layer thickness ratio L1_{TH}/L2_{TH} of at least about 0.7,
where L1_{TH} is the thickness of the first layer and L2_{TH} is the thickness of the second layer,
wherein the adhesive layer is disposed between the substrate and the first layer, and
wherein the first layer is disposed between the adhesive layer and the second layer.
